(19) United States
(12) Patent Application Publication
(10) Pub. No.: US 2013/0264191 A1
(43) Pub. Date: Oct. 10, 2013

(54) SHIELD MESH FOR SPUTTERING OF A THIN FILM ON A SUBSTRATE

(71) Applicants: Fritz Martin Schulmeyer, Arvada, CO (US); Robert Dwayne Gossman, Aurora, CO (US)

(72) Inventors: Fritz Martin Schulmeyer, Arvada, CO (US); Robert Dwayne Gossman, Aurora, CO (US)

(73) Assignee: PRIMESTAR SOLAR, INC., Arvada, CO (US)

(21) Appl. No.: 13/441,126

(22) Filed: Apr. 6, 2012

(51) Int. Cl. C23C 14/34

(52) U.S. Cl. 204/192.12; 204/298.11; 204/298.02

(57) ABSTRACT

Sputtering chambers including a mesh material covering the inner surfaces within the chamber are generally provided. The sputtering chamber can include a cathode positioned in working proximity to a sputtering target, a target shield extending over at least a portion of the sputtering target while leaving a majority of the sputtering target exposed, and a mesh material positioned on an outer surface of the target shield. Additionally, or alternatively, the sputtering chamber candefine a pair of side walls, a top wall, and a bottom wall, with the mesh material positioned on an inner surface of the side walls, the top wall, and/or the bottom wall. Methods are also generally provided for sputtering a target in a sputtering chamber to deposit a thin film on a substrate.

### FIELD OF THE INVENTION

The subject matter disclosed herein relates generally to methods of sputtering a thin film on a substrate. More particularly, the subject matter disclosed herein relates to methods of suppressing large scale flaking of the target during sputtering of a thin film layer on a substrate.

### BACKGROUND OF THE INVENTION

Sputtering deposition involves ejecting material from a target (i.e., the material source), and depositing the ejected material onto the substrate to form the film. A plasma discharge is sustained between the target and the substrate in the sputtering chamber during deposition by coupling RF or DC power from an electrical power source to the plasma, where the target acts as a cathode having a negative potential during sputtering.

Due to the charge build-up on the cathode, arcs can sometimes form between the target (i.e., the cathode) and other materials in the chamber having an anode potential (e.g., the chamber walls, the plasma field, the substrate, the substrate carrier, etc.). Once formed, the arc can continue to be supplied power (via the electrical power source) and can result in significant damage to the target. Such damage can result in non-uniform layers being formed, as well as delays in the manufacturing process.

For example, the sputtering process can cause a build-up of metal on the shield wall of the chamber. This metal can then flake off of the shield, in the form of large scale flaking, during subsequent sputtering, which can lead to arcing (e.g,. between the target and the flake) that can short the cathode.

Thus, a need exists for methods of suppressing cathode shorting and/or arc formation during sputtering and minimizing its effect on the deposition process, particularly in large-scale, mass manufacturing processes.

### BRIEF DESCRIPTION OF THE INVENTION

Aspects and advantages of the invention will be set forth in part in the following description, or may be obvious from the description, or may be learned through practice of the invention.

A sputtering chamber is generally provided, in one embodiment, that includes a cathode positioned in working proximity to a sputtering target, a target shield extending over at least a portion of the sputtering target while leaving a majority of the sputtering target exposed, and a mesh material positioned on an outer surface of the target shield. For example, the target shield can perimetrically surround the sputtering target, and the mesh material can perimetrically surround the target shield. Additionally, or alternatively, the sputtering chamber can, in certain embodiments, define a pair of side walls, a top wall, and a bottom wall, with the mesh material positioned on an inner surface of the side walls, the top wall, and/or the bottom wall.

For example, the mesh material can comprise a plurality of metal wires (e.g., steel, stainless steel, nickel, a nickel superalloy, aluminum, titanium, molybdenum, or alloys thereof, or combinations thereof). In one embodiment, the sputtering target can include a metal, and the metal wires can be constructed from the metal included in the sputtering target. The plurality of metal wires can include intersecting metal wires (e.g., defining a woven web or a welded web). For instance, the mesh material can define voids that are at least 75% of the surface area of the mesh material.

Methods are also generally provided for sputtering a target in a sputtering chamber to deposit a thin film on a substrate (e.g., using any of the sputtering chambers). For example, the method can include forming a plasma in the sputtering chamber between the target and the substrate such that atoms are ejected from the target, with the sputtering chamber having a target shield extending over at least a portion of the target while leaving a majority of the target exposed and a mesh material positioned between the plasma and the target shield. The atoms ejected from the target can be deposited onto the substrate to form the thin film.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWING

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary sputtering chamber that has a vertical orientation;

FIG. 2 shows a close-up view of a corner of the exemplary sputtering chamber of FIG. 1 with the mesh material positioned between the target and the shield;

FIG. 3 shows a view of the target from inside the sputtering chamber of FIG. 1,

FIG. 4 shows a cross-sectional view of another exemplary sputtering chamber;

FIG. 5 shows a general schematic of the system for detecting and suppressing arcs formed in the exemplary sputtering chamber of FIG. 1;

FIG. 6 shows an exploded view of one exemplary embodiment of the mesh material;

FIG. 7 shows an exploded view of another exemplary embodiment of the mesh material.

FIG. 8 shows an exemplary photovoltaic device having multiple thin film layers that can be formed according to one embodiment;

FIG. 9 shows a general schematic of another exemplary sputtering chamber that has a horizontal orientation;

FIG. 10 shows a general schematic of a cross-sectional view of the exemplary sputtering chamber of FIG. 9; and,

FIG. 11 shows a general schematic of another cross-sectional view of the exemplary sputtering chamber of FIG. 9.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment, can be used with another embodiment to yield a still further embodiment. Thus, it is intended that the present invention covers such modifications and variations as come within the scope of the appended claims and their equivalents.

Apparatus and methods are generally provided of inhibiting and/or suppressing shorting of the cathode (i.e., the sputtering target) during sputtering of a thin film on a substrate. The suppression of shorts and/or arcs formed during the sputtering process can allow for better uniformity of the thin film layer being formed throughout the sputtering process. For instance, the apparatus and methods can reduce the size of any flakes (e.g., formed on the side(s) of the sputtering chamber during the process) present in the apparatus to a relatively small size that inhibits the formation of an arc between the flake and the plasma during sputtering. That is, the inclusion of a mesh material protecting the inner surface of the walls of the sputtering chamber promotes the formation of much smaller flakes (relative to flakes that would otherwise form on the inner surface without the mesh material present). Such relatively small flakes are much less prone to act as arcing sites within the sputtering chamber.

That is, not only can the thin film layer have better uniformity on the individual substrates, but the thin film layers on each substrate can also be substantially uniform from substrate to substrate. Thus, the presently disclosed apparatus and methods are particularly useful during mass production of thin film substrates in a commercial setting, such as during the formation of cadmium sulfide layers during the mass production of cadmium telluride based thin film photovoltaic devices. Although the present disclosure is discussed in reference to sputtering thin film layers during the manufacture of cadmium telluride based thin film photovoltaic devices, the following discussion is not intended to limit the broader aspects of the present disclosure.

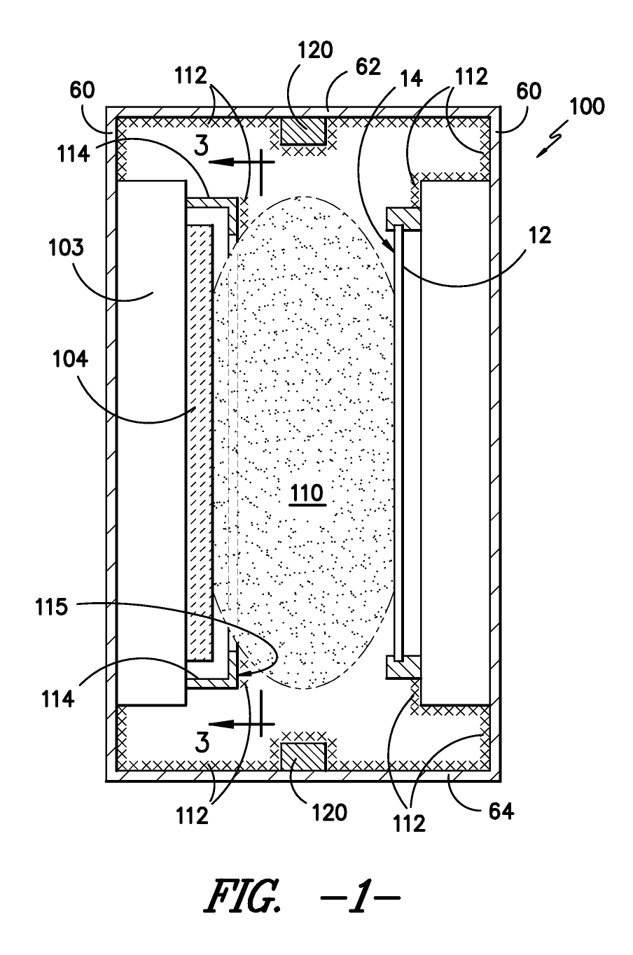

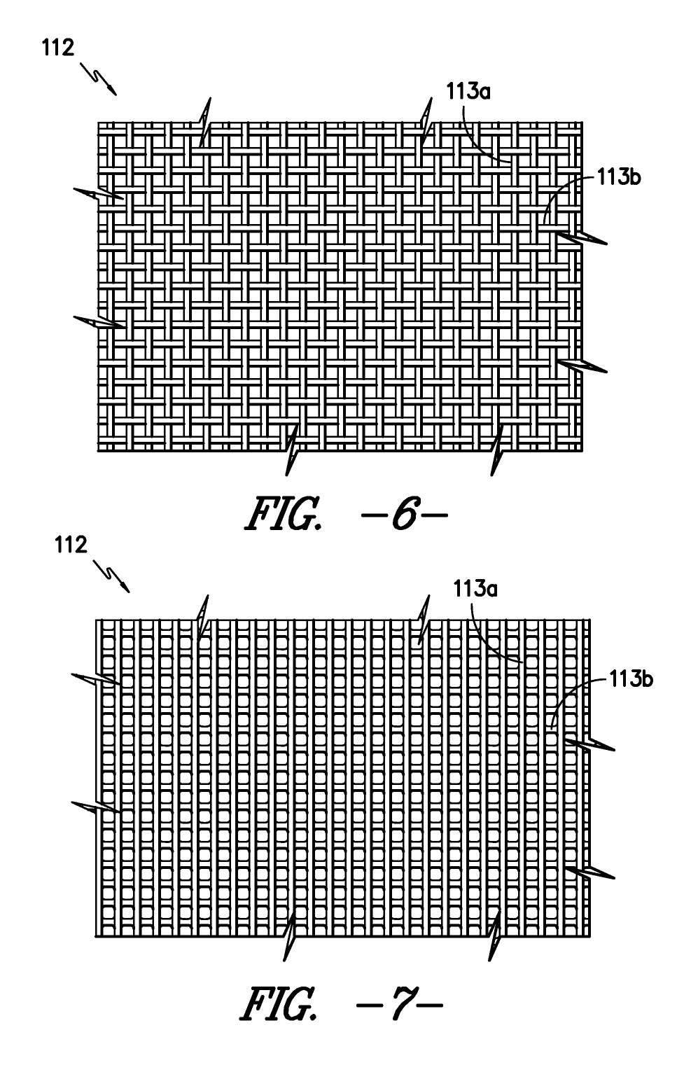

FIG. 1 shows a general schematic as a cross-sectional view of an exemplary RF sputtering chamber 100 according to one embodiment of the present invention. As shown in FIG. 5, a RF power source 102 is configured to control and supply RF power to the chamber 100. The RF power can be in the form of AC current having a frequency of about 500 kHz to 40 MHz, such as about 10 MHz to about 15 MHz (e.g,. 13.56 MHz).

As shown, the power source applies a voltage to the cathode 103 to create a voltage potential between the cathode 103 and an anode formed by the chamber wall and/or the top support 106 and bottom support 107 via wires 108 and 109, respectively. Generally, the transparent substrate 12 (e.g., a glass) is positioned within the sputtering chamber 100 such that the thin film 14 is formed on the substrate 12 facing the target 104 on the cathode 103.

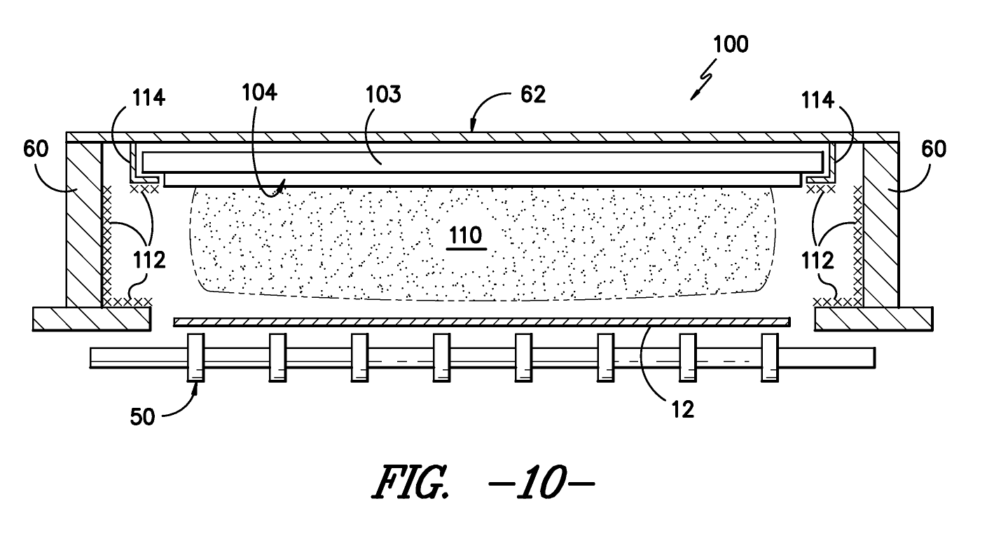

A plasma 110 is created once the sputtering atmosphere is ignited, and is sustained in response to the voltage potential between the cathode 103 and the anode. The voltage potential causes the plasma ions within the plasma field 110 to accelerate toward the target 104 on the cathode 103, since the target 104 is positioned in working proximity to the cathode 103 (e.g., adjacent to). Thus, the plasma 110 and the voltage potential cause atoms from the target 104 to be ejected toward the transparent substrate 12. As such, the target 104 acts as the source material for the formation of the thin film layer (e.g., the cadmium sulfide layer 18 shown in FIG. 8) on the transparent substrate 10. The target 104 can be a semiconducting target, such as cadmium sulfide, or mixtures thereof. Additionally, in some embodiments, a plurality of targets 104 can be utilized. A plurality of targets 104 can be particularly useful to form a layer including several types of materials (e.g., co-sputtering). The sputtering atmosphere forming the plasma field 110 generally contains an inert gas, such as argon. However, oxygen can be present in the sputtering atmosphere in certain embodiments. It is noted that the target 104 and cathode 103 can form one structure, in certain embodiments, instead of the separate structures shown in FIG. 1.

During the sputtering process within the sputtering chamber 100, the sputtered material can also build up on the walls of the sputtering chamber, especially on the exposed surfaces within the chamber 100 that are exposed to the plasma 110. For example, the inner surfaces of the chamber side walls 60, the top wall 62, and the bottom wall 64. Additionally, the outer surfaces of the target shield 114 (i.e., opposite of the target 104) are exposed to the plasma and are particularly susceptible to build-up of the sputtered material thereon. Upon sufficient build-up over an extended sputtering process (e.g., a large-scale, continuous manufacturing process), the material deposited on such surfaces can be sufficiently thick to flake off under its own weight. Upon flaking, this loose semi-conducting material can lead to arc formation between (1) the cathode 103 and/or the target 104 and/or the plasma 110 and (2) the flakes, which can short the cathode.

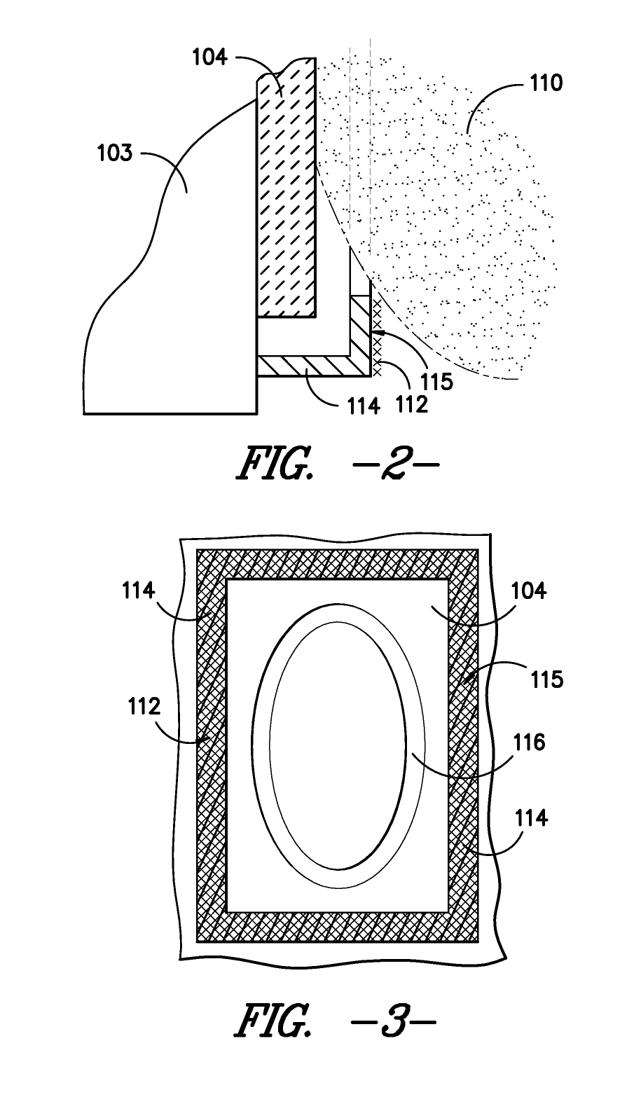

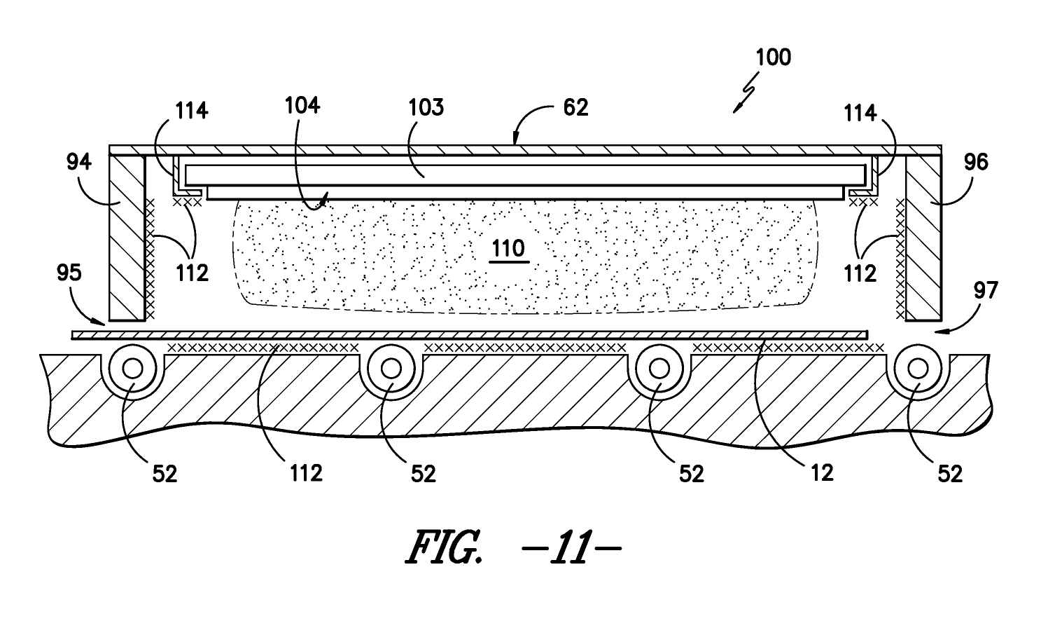

This build-up can occur on any type of sputtering chamber 100, such as the vertically oriented chamber 100 shown in FIGS. 1-5 and the horizontally oriented chamber 100 shown in FIGS. 9-11. Thus, although FIGS. 1-5 are primarily referenced in the following discussion, it is to be understood that the following discussion equally applies to the horizontally oriented chamber 100 shown in FIGS. 9-11.

As shown in FIGS. 1 and 5, a mesh material 112 is positioned between the plasma 110 and exposed surfaces within the chamber 100. As shown, the mesh material 112 covers the outer surface 115 of the target shield 114, the inner surface of the side walls 60, the inner surface of the top wall 62, the inner surface of the bottom wall 64. Other surfaces within the chamber 100 that could be exposed to the plasma 110 during the sputtering process may also be covered with the mesh material 112. For example, referring to the horizontal embodiment shown in FIGS. 9-11, the mesh material 112 can be positioned within the conveying system 50, such as covering the exposed area between the conveyor rollers 52. Additionally, as shown in FIGS. 9-11, the mesh material 112 can be positioned on the inner surface of the entry wall 94 around the entry slot 95 and on the inner surface of the exit wall 96 around the exit slot 97.

In one particular embodiment, the mesh material 112 can be positioned on the outer surface 115 (i.e., the surface facing the plasma 110) of the target shield 114. Referring to FIG. 3, for example, the target shield 114 can perimetrically surround the target 104. In this exemplary embodiment, the mesh material 112 can also perimetrically surround the target shield 114.

Additionally, or alternatively, the mesh material 112 may be positioned on the inner surface of the side walls 60, the top wall 62, and/or the bottom wall 64. For example, the mesh material can cover at least about 90% of any exposed surface area of the side walls, the top wall, and the bottom wall, such as about 95% to 100%.

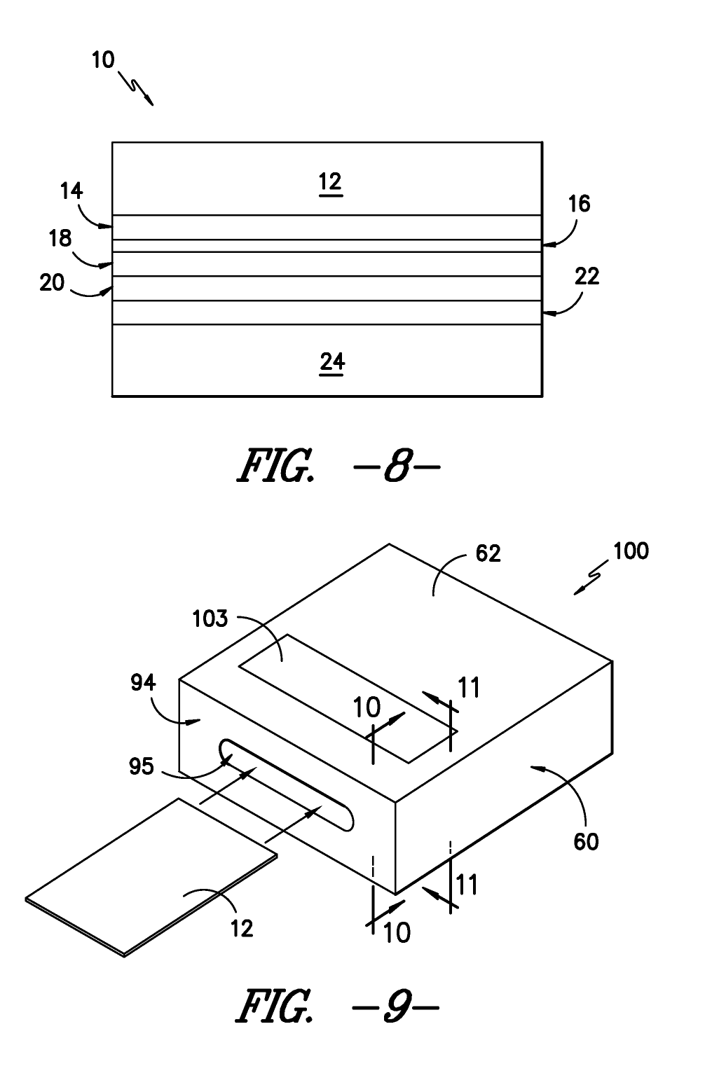

The mesh material 112 can be configured to inhibit build-up on such exposed surfaces to suppress the formation of the sputtered material thereon that could eventually form large-scale flakes. For example, the mesh material 112 can be a plurality of wires that are interconnected to form a pattern. Referring to FIGS. 6 and 7, a plurality of intersecting wires 113a, 113b are shown forming the mesh material 112, suitable for use in the chamber 100 of FIGS. 1-5 and 9-11. FIG. 6 shows that the first wires 113a, oriented in a first direction, are woven with the second wires 113b oriented in a second direction that is substantially perpendicular to the first direction. FIG. 7 shows a similar pattern of intersecting wires 113a, 113b in which the first wires 113a, oriented in a first direction, are welded to the second wires 113b oriented in a second direction that is substantially perpendicular to the first direction.

The pattern of the mesh material 112 can define voids in the surface area of the mesh material, allowing the sputtered material to pass through. For example, the void space is defined between the plurality of intersecting wires 113a, 113b in the embodiments shown in FIGS. 6 and 7. The total void space can, in particular embodiments, define at least 75% of the total surface area of the mesh material, such as about 75% to about 95% of the total surface area of the mesh material.

The mesh material 112 can be made of any suitable material configured to withstand the conditions of the sputtering chamber 100 during use. For example, referring to the intersecting wires 113a, 113b of FIGS. 6 and 7, the wires can be constructed from a metal material (e.g., a metal, metal alloy, etc.). Particularly suitable metal materials include, but are not limited to, steel, stainless steel, nickel, nickel superalloys (e.g., an austenitic nickel-chromium-based superalloy available under the tradename Inconel® from Special Metals Corporation of New Hartford, N.Y., or the nickel superalloys available under the tradename Hastelloy® from Haynes International, Inc. of Kokomo, Ind.), aluminum, titanium, molybdenum, or alloys thereof, or combinations thereof.

In one particular embodiment, the mesh material can be constructed from a material that is included within the target. For instance, if the target includes a metal(s) or a metal(s) oxide, then the mesh material can be constructed from a metal that is present in the target. For example, if the target includes nickel, the mesh material can be constructed from nickel. Thus, in this embodiment, even if a portion of the mesh material is exposed to the plasma and sputtered over time by during use, the sputtered mesh material will not contaminate the deposited thin film on the substrate.

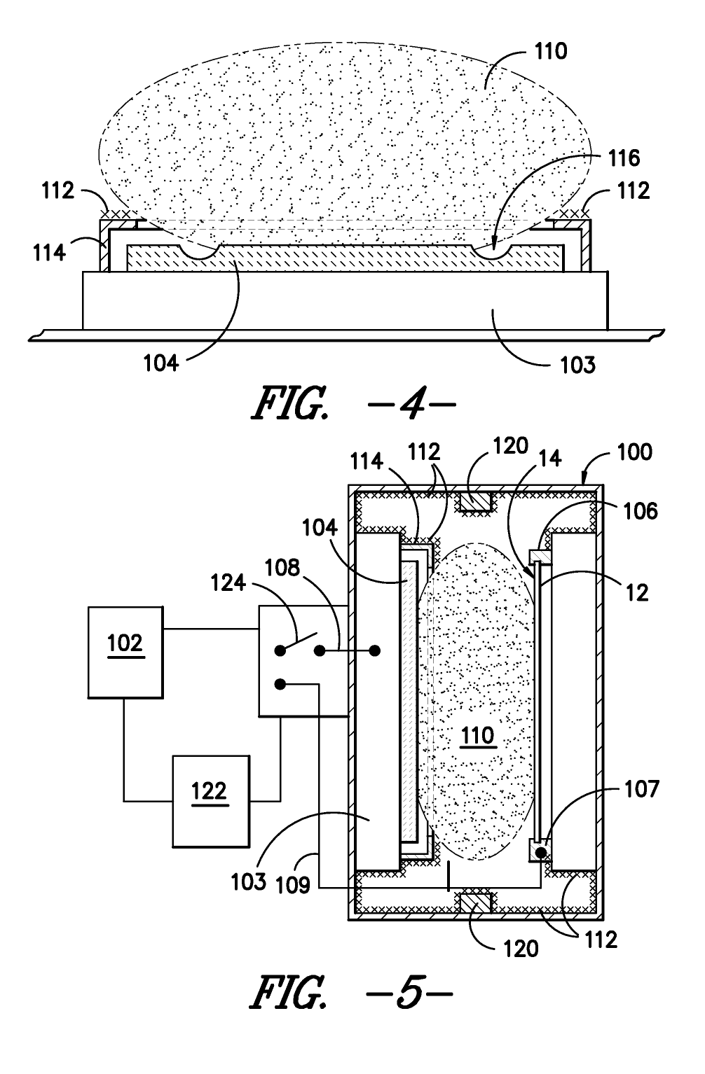

As shown in FIG. 3 and FIG. 4, the cathode 103 (i.e., the target) can be exposed to a plasma field 110 during sputtering to deposit a thin film onto the substrate 12. FIG. 3 also shows grooves 116 that can form in the cathode 103 during a prolonged sputtering process. These grooves 116 generally represent the target material that has been ejected off of the cathode 103 after sputtering for a prolonged period.

Although only a single power source 102 is shown, the voltage potential can be realized through the use of multiple power sources coupled together. Additionally, the exemplary sputtering chamber 100 is shown having a vertical orientation, although any other configuration can be utilized. When multiple power sources are utilized, the power from each source can be simultaneously interrupted to suppress an arc upon the detection of the arc signature.

The mesh material used in the sputtering of a thin film on a substrate can be particularly useful in the formation of a cadmium telluride device, such as in the cadmium telluride thin film photovoltaic device disclosed in U.S. Publication No. 2009/0194165 of Murphy, et al. titled “Ultra-high Current Density Cadmium Telluride Photovoltaic Modules.” In particular, the mesh material can be useful during the formation of any thin film layer formed via sputtering, including but not limited to a transparent conductive oxide layer, a resistive transparent buffer layer, and/or a cadmium sulfide layer, in the formation of a cadmium telluride thin film photovoltaic device, especially during the mass production of such devices.

FIG. 8 represents an exemplary cadmium telluride thin film photovoltaic device 10. The exemplary device 10 of FIG. 8 includes a top sheet of glass 12 employed as the substrate. In this embodiment, the glass 12 can be referred to as a “superstrate,” since it is the substrate on which the subsequent layers are formed, but it faces upwards to the radiation source (e.g., the sun) when the cadmium telluride thin film photovoltaic device 10 is in used. The top sheet of glass 12 can be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers. In one embodiment, the glass 12 can be a low iron float glass containing less than about 0.15% by weight iron (Fe), and may have a transmissiveness of about 0.9 or greater in the spectrum of interest (e.g., wavelengths from about 300 nm to about 900 nm).

A transparent conductive oxide (TCO) layer 14 is shown on the glass 12 of the exemplary device 10 of FIG. 8. The TCO layer 14 allows light to pass through with minimal absorption while also allowing electric current produced by the device 10 to travel sideways to opaque metal conductors (not shown). For instance, the TCO layer 14 can have a sheet resistance less than about 30 ohm per square, such as from about 4 ohm per square to about 20 ohm per square (e.g., from about 8 ohm per square to about 15 ohm per square). The TCO layer 14 generally includes at least one conductive oxide, such as tin oxide, zinc oxide, or indium tin oxide, or mixtures thereof. Additionally, the TCO layer 14 can include other conductive, transparent materials. The TCO layer 14 can also include zinc stannate and/or cadmium stannate.

The TCO layer 14 can be formed by sputtering, chemical vapor deposition, spray pyrolysis, or any other suitable deposition method. In one particular embodiment, the TCO layer 14 can be formed by sputtering, either DC sputtering or RF sputtering, on the glass 12. For example, a cadmium stannate layer can be formed by sputtering a hot-pressed target containing stoichiometric amounts of SnO₂ and CdO onto the glass 12 in a ratio of about 1 to about 2. The cadmium stannate can alternatively be prepared by using cadmium acetate and tin (II) chloride precursors by spray pyrolysis.

In certain embodiments, the TCO layer 14 can have a thickness between about 0.1 μm and about 1 μm, for example from about 0.1 μm to about 0.5 μm, such as from about 0.25 μm to about 0.35 μm. Suitable flat glass substrates having a TCO layer 14 formed on the superstrate surface can be purchased commercially from various glass manufactures and suppliers. For example, a particularly suitable glass 12 including a TCO layer 14 includes a glass commercially available under the name TEC 15 TCO from Pilkington North America Inc. (Toledo, Ohio), which includes a TCO layer having a sheet resistance of 15 ohms per square.

A resistive transparent buffer layer 16 (RTB layer) is shown on the TCO layer 14 on the exemplary cadmium telluride thin film photovoltaic device 10. The RTB layer 16 is generally more resistive than the TCO layer 14 and can help protect the device 10 from chemical interactions between the TCO layer 14 and the subsequent layers during processing of the device 10. For example, in certain embodiments, the RTB layer 16 can have a sheet resistance that is greater than about 1000 ohms per square, such as from about 10 kOhms per square to about 1000 MOhms per square. The RTB layer 16 can also have a wide optical bandgap (e.g., greater than about 2.5 eV, such as from about 2.7 eV to about 3.0 eV).

Without wishing to be bound by a particular theory, it is believed that the presence of the RTB layer 16 between the TCO layer 14 and the cadmium sulfide layer 18 can allow for a relatively thin cadmium sulfide layer 18 to be included in the device 10 by reducing the possibility of interface defects (i.e., “pinholes” in the cadmium sulfide layer 18) creating shunts between the TCO layer 14 and the cadmium telluride layer 22. Thus, it is believed that the RTB layer 16 allows for improved adhesion and/or interaction between the TCO layer 14 and the cadmium telluride layer 22, thereby allowing a relatively thin cadmium sulfide layer 18 to be formed thereon without significant adverse effects that would otherwise result from such a relatively thin cadmium sulfide layer 18 formed directly on the TCO layer 14.

The RTB layer 16 can include, for instance, a combination of zinc oxide (ZnO) and tin oxide (SnO₂), which can be referred to as a zinc tin oxide layer (“ZTO”). In one particular embodiment, the RTB layer 16 can include more tin oxide than zinc oxide. For example, the RTB layer 16 can have a composition with a stoichiometric ratio of ZnO/SnO₂ between about 0.25 and about 3, such as in about an one to two (1:2) stoichiometric ratio of tin oxide to zinc oxide. The RTB layer 16 can be formed by sputtering, chemical vapor deposition, spraying pryolysis, or any other suitable deposition method. In one particular embodiment, the RTB layer 16 can be formed by sputtering, either DC sputtering or RF sputtering, on the TCO layer 14. For example, the RTB layer 16 can be deposited using a DC sputtering method by applying a DC current to a metallic source material (e.g., elemental zinc, elemental tin, or a mixture thereof) and sputtering the metallic source material onto the TCO layer 14 in the presence of an oxidizing atmosphere (e.g., O₂ gas). When the oxidizing atmosphere includes oxygen gas (i.e., O₂), the atmosphere can be greater than about 95% pure oxygen, such as greater than about 99%.

In certain embodiments, the RTB layer 16 can have a thickness between about 0.075 μm and about 1 μm, for example from about 0.1 μm to about 0.5 μm. In particular embodiments, the RTB layer 16 can have a thickness between about 0.08 μm and about 0.2 μm, for example from about 0.1 μm to about 0.15 μm.

A cadmium sulfide layer 18 is shown on resistive transparent buffer layer 16 of the exemplary device 10 of FIG. 8. The cadmium sulfide layer 18 is a n-type layer that generally includes cadmium sulfide (CdS) but may also include other materials, such as zinc sulfide, cadmium zinc sulfide, etc., and mixtures thereof as well as dopants and other impurities. In one particular embodiment, the cadmium sulfide layer may include oxygen up to about 25% by atomic percentage, for example from about 5% to about 20% by atomic percentage. The cadmium sulfide layer 18 can have a wide band gap (e.g., from about 2.25 eV to about 2.5 eV, such as about 2.4 eV) in order to allow most radiation energy (e.g., solar radiation) to pass. As such, the cadmium sulfide layer 18 is considered a transparent layer on the device 10.

The cadmium sulfide layer 18 can be formed by sputtering, chemical vapor deposition, chemical bath deposition, and other suitable deposition methods. In one particular embodiment, the cadmium sulfide layer 18 can be formed by sputtering, either direct current (DC) sputtering or radio frequency (RF) sputtering, on the resistive transparent buffer layer 16. Sputtering deposition generally involves ejecting material from a target, which is the material source, and depositing the ejected material onto the substrate to form the film. DC sputtering generally involves applying a voltage to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) having a pressure between about 1 mTorr and about 20 mTorr.

Due to the presence of the resistive transparent layer 16, the cadmium sulfide layer 18 can have a thickness that is less than about 0.1 μm, such as between about 10 nm and about 100 nm, such as from about 50 nm to about 80 nm, with a minimal presence of pinholes between the resistive transparent layer 16 and the cadmium sulfide layer 18. Additionally, a cadmium sulfide layer 18 having a thickness less than about 0.1 μm reduces any adsorption of radiation energy by the cadmium sulfide layer 18, effectively increasing the amount of radiation energy reaching the underlying cadmium telluride layer 22.

A cadmium telluride layer 20 is shown on the cadmium sulfide layer 18 in the exemplary cadmium telluride thin film photovoltaic device 10 of FIG. 8. The cadmium telluride layer 20 is a p-type layer that generally includes cadmium telluride (CdTe) but may also include other materials. As the p-type layer of device 10, the cadmium telluride layer 20 is the photovoltaic layer that interacts with the cadmium sulfide layer 18 (i.e., the n-type layer) to produce current from the adsorption of radiation energy by absorbing the majority of the radiation energy passing into the device 10 due to its high absorption coefficient and creating electron-hole pairs. For example, the cadmium telluride layer 20 can generally be formed from cadmium telluride and can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 20) across the junction to the n-type side (i.e., the cadmium sulfide layer 18) and, conversely, holes may pass from the n-type side to the p-type side. Thus, the p-n junction formed between the cadmium sulfide layer 18 and the cadmium telluride layer 20 forms a diode in which the charge imbalance leads to the creation of an electric field spanning the p-n junction. Conventional current is allowed to flow in only one direction and separates the light induced electron-hole pairs.

The cadmium telluride layer 20 can be formed by any known process, such as vapor transport deposition, chemical vapor deposition (CVD), spray pyrolysis, electro-deposition, sputtering, close-space sublimation (CSS), etc. In one particular embodiment, the cadmium sulfide layer 18 is deposited by a sputtering and the cadmium telluride layer 20 is deposited by close-space sublimation. In particular embodiments, the cadmium telluride layer 20 can have a thickness between about 0.1 μm and about 10 μm, such as from about 1 μm and about 5 μm. In one particular embodiment, the cadmium telluride layer 20 can have a thickness between about 2 μm and about 4 μm, such as about 3 μm.

A series of post-forming treatments can be applied to the exposed surface of the cadmium telluride layer 20. These treatments can tailor the functionality of the cadmium telluride layer 20 and prepare its surface for subsequent adhesion to the back contact layer(s) 22. For example, the cadmium telluride layer 20 can be annealed at elevated temperatures (e.g., from about 350° C. to about 500° C., such as from about 375° C. to about 424° C.) for a sufficient time (e.g., from about 1 to about 10 minutes) to create a quality p-type layer of cadmium telluride. Without wishing to be bound by theory, it is believed that annealing the cadmium telluride layer 20 (and the device 10) converts the normally n-type cadmium telluride layer 20 to a p-type cadmium telluride layer 20 having a relatively low resistivity. Additionally, the cadmium telluride layer 20 can recrystallize and undergo grain growth during annealing.

Annealing the cadmium telluride layer 20 can be carried out in the presence of cadmium chloride in order to dope the cadmium telluride layer 20 with chloride ions. For example, the cadmium telluride layer 20 can be washed with an aqueous solution containing cadmium chloride then annealed at the elevated temperature.

In one particular embodiment, after annealing the cadmium telluride layer 20 in the presence of cadmium chloride, the surface can be washed to remove any cadmium oxide formed on the surface. This surface preparation can leave a Te-rich surface on the cadmium telluride layer 20 by removing oxides from the surface, such as CdO, CdTeO₃, CdTe₂O₅, etc. For instance, the surface can be washed with a suitable solvent (e.g., ethylenediamine also known as 1,2 diaminoethane or “DAE”) to remove any cadmium oxide from the surface.

Additionally, copper can be added to the cadmium telluride layer 20. Along with a suitable etch, the addition of copper to the cadmium telluride layer 20 can form a surface of copper-telluride on the cadmium telluride layer 20 in order to obtain a low-resistance electrical contact between the cadmium telluride layer 20 (i.e., the p-type layer) and the back contact layer(s). Specifically, the addition of copper can create a surface layer of cuprous telluride (Cu₂Te) between the cadmium telluride layer 20 and the back contact layer 22. Thus, the Te-rich surface of the cadmium telluride layer 20 can enhance the collection of current created by the device through lower resistivity between the cadmium telluride layer 20 and the back contact layer 22.

Copper can be applied to the exposed surface of the cadmium telluride layer 20 by any process. For example, copper can be sprayed or washed on the surface of the cadmium telluride layer 20 in a solution with a suitable solvent (e.g., methanol, water, or the like, or combinations thereof) followed by annealing. In particular embodiments, the copper may be supplied in the solution in the form of copper chloride, copper iodide, or copper acetate. The annealing temperature is sufficient to allow diffusion of the copper ions into the cadmium telluride layer 20, such as from about 125° C. to about 300° C. (e.g. from about 150° C. to about 200° C.) for about 5 minutes to about 30 minutes, such as from about 10 to about 25 minutes.

A back contact layer 22 is shown on the cadmium telluride layer 20. The back contact layer 22 generally serves as the back electrical contact, in relation to the opposite, TCO layer 14 serving as the front electrical contact. The back contact layer 22 can be formed on, and in one embodiment is in direct contact with, the cadmium telluride layer 20. The back contact layer 22 is suitably made from one or more highly conductive materials, such as elemental nickel, chromium, copper, tin, aluminum, gold, silver, technetium or alloys or mixtures thereof. Additionally, the back contact layer 22 can be a single layer or can be a plurality of layers. In one particular embodiment, the back contact layer 22 can include graphite, such as a layer of carbon deposited on the p-layer followed by one or more layers of metal, such as the metals described above. The back contact layer 22, if made of or comprising one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 22, can be from about 0.1 μm to about 1.5 μm in thickness.

The encapsulating substrate 24 (e.g., an encapsulating glass) is also shown in the exemplary cadmium telluride thin film photovoltaic device 10 of FIG. 8.

Other components (not shown) can be included in the exemplary device 10, such as bus bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically generated current to convenient locations for connection to a device or other system using the generated electric. A convenient means for achieving such series connections is to laser scribe the device to divide the device into a series of cells connected by interconnects. In one particular embodiment, for instance, a laser can be used to scribe the deposited layers of the semiconductor device to divide the device into a plurality of series connected cells.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A sputtering chamber comprising:
a cathode positioned in working proximity to a sputtering target;
a target shield extending over at least a portion of the sputtering target while leaving a majority of the sputtering target exposed; and,
a mesh material positioned on an outer surface of the target shield.

2. The sputtering chamber as in claim 1, wherein the mesh material comprises a plurality of metal wires.

3. The sputtering chamber as in claim 2, wherein the metal wires comprise steel, stainless steel, nickel, a nickel superalloy, aluminum, titanium, molybdenum, or alloys thereof, or combinations thereof.

4. The sputtering chamber as in claim 2, wherein the sputtering target comprises a metal, and wherein the metal wires are constructed from the metal included in the sputtering target.

5. The sputtering chamber as in claim 2, wherein the plurality of metal wires includes intersecting metal wires.

6. The sputtering chamber as in claim 5, wherein the plurality of metal wires defines a woven web.

7. The sputtering chamber as in claim 5, wherein the plurality of metal wires defines a welded web.

8. The sputtering chamber as in claim 1, wherein the mesh material defines voids that are at least 75% of the surface area of the mesh material.

9. The sputtering chamber as in claim 1, wherein the sputtering chamber defines a pair of side walls, a top wall, and a bottom wall, and wherein the mesh material is also positioned on an inner surface of the side walls, the top wall, or the bottom wall.

10. The sputtering chamber as in claim 9, wherein the mesh material is also positioned on an inner surface of the side walls, the top wall, and the bottom wall.

11. The sputtering chamber as in claim 1, wherein the target shield perimetrically surrounds the sputtering target, and wherein the mesh material perimetrically surrounds the target shield.

12. A sputtering chamber defining a pair of side walls, a top wall, and a bottom wall, the sputtering chamber comprising:
a cathode positioned in working proximity to a sputtering target; and,
a mesh material positioned on an inner surface of the side walls, the top wall, or the bottom wall.

13. The sputtering chamber as in claim 12, wherein the mesh material comprises a plurality of metal wires.

14. The sputtering chamber as in claim 13, wherein the metal wires comprise steel, stainless steel, nickel, a nickel superalloy, aluminum, titanium, molybdenum, or alloys thereof, or combinations thereof.

15. The sputtering chamber as in claim 13, wherein the sputtering target comprises a metal, and wherein the metal wires are constructed from the metal included in the sputtering target.

16. The sputtering chamber as in claim 13, wherein the plurality of metal wires includes intersecting metal wires.

17. The sputtering chamber as in claim 12, wherein the mesh material is also positioned on the inner surface of the side walls, the top wall, and the bottom wall.

18. The sputtering chamber as in claim 17, wherein the mesh material covers at least about 90% of any exposed surface area of the side walls, the top wall, and the bottom wall.

19. A method of sputtering a target in a sputtering chamber to deposit a thin film on a substrate, the method comprising:
forming a plasma in the sputtering chamber between the target and the substrate such that atoms are ejected from the target, wherein the sputtering chamber comprises a target shield extending over at least a portion of the target while leaving a majority of the target exposed, and a mesh material positioned between the plasma and the target shield; and,
depositing the atoms ejected from the target onto the substrate to form the thin film.

20. The method as in claim 14, wherein the mesh material comprises a plurality of metal wires.
